(19) United States
(12) Patent Application Publication
(10) Pub. No.: US 2018/0157540 A1
(43) Pub. Date: Jun. 7, 2018

(54) CONTROL DEVICE AND CONTROL METHOD

(71) Applicant: FUJITSU LIMITED, Kawasaki-shi (JP)

(72) Inventor: Noboru Yoneoka, Kawasaki (JP)

(73) Assignee: FUJITSU LIMITED, Kawasaki-shi (JP)

(21) Appl. No.: 15/819,771

(22) Filed: Nov. 21, 2017

(30) Foreign Application Priority Data
Dec. 7, 2016 (JP) 2016-237911

(51) Int. Cl. G06F 9/50; H03K 19/00; H03K 19/0175; G06F 1/32

(52) U.S. Cl. CPC G06F 9/5083; G06F 1/3228; H03K 19/017581; H03K 19/0008

(57) ABSTRACT

A control device includes, a semiconductor device including a processor and a programmable circuit, another programmable circuit coupled to the semiconductor device and another processor coupled to the semiconductor device and the other programmable circuit and configured to, when it is detected that power consumed by the semiconductor device exceeds a threshold value, specify a first task from among tasks each of which logic is programmed in the programmable circuit, a data transfer cost for the first task between the processor and the programmable circuit being smaller than each of data transfer costs for other tasks included in the tasks, program the logic of the first task into the other programmable circuit, and control the first task to be executed by the logic of the first task in the other programmable circuit.

### CROSS-REFERENCE TO RELATED APPLICATION

This application is based upon and claims the benefit of priority of the prior Japanese Patent Application No. 2016-237911, filed on Dec. 7, 2016, the entire contents of which are incorporated herein by reference.

### FIELD

The embodiments discussed herein are related to a control device for information processing and a control method for information processing.

### BACKGROUND

Recently, attention has been paid to an information processing device that causes a programmable device such as a field-programmable gate array (FPGA) for dynamically reconfiguring logic to function as an accelerator. For example, an operation that satisfies various requested items is achieved by preparing, for each of tasks to be executed by the FPGA, multiple circuit information items indicating difference processing characteristics and loading any of the multiple circuit information items in the FPGA based on an operational state of a system (refer to, for example, Japanese Laid-open Patent Publication No. 2007-179358).

In addition, a cryptographic processing transaction is efficiently executed by using multiple central processing unit (CPU) cores installed in an FPGA for an interface with an external and for cryptographic processing and causing two CPUs to coordinate with each other and operate (for example, Japanese Laid-open Patent Publications No. 2007-179358 and 2009-296195).

### SUMMARY

According to an aspect of the invention, a control device includes, a semiconductor device including a processor and a programmable circuit, another programmable circuit coupled to the semiconductor device and another processor coupled to the semiconductor device and the other programmable circuit and configured to, when it is detected that power consumed by the semiconductor device exceeds a threshold value, specify a first task from among tasks each of which logic is programmed in the programmable circuit, a data transfer cost for the first task between the processor and the programmable circuit being smaller than each of data transfer costs for other tasks included in the tasks, program the logic of the first task into the other programmable circuit, and control the first task to be executed by the logic of the first task in the other programmable circuit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an embodiment of an information processing device, a method for controlling the information processing device, and a control program of the information processing device;

FIG. 2 is a diagram illustrating an example of operations of the information processing device illustrated in FIG. 1;

FIG. 3 is a diagram illustrating an example of a process of the control program executed by a CPU illustrated in FIG. 1;

FIG. 4 is a diagram illustrating another example of operations of the information processing device illustrated in FIG. 1;

FIG. 5 is a diagram illustrating still another example of operations of the information processing device;

FIG. 6 is a diagram illustrating an example of operations of an information processing device according to another embodiment; and

FIG. 7 is a diagram illustrating an example of a process of the control program executed by the CPU illustrated in a state (a0) of FIG. 6.

### DESCRIPTION OF EMBODIMENTS

In conventional techniques, in the case where a CPU and an FPGA are installed in a single semiconductor device, the CPU and the FPGA operate in such a manner that the total of power consumed by the CPU and power consumed by the FPGA is equal to or lower than power allowed to be consumed by the semiconductor device. Thus, as the number of tasks executed by the FPGA increases, power allowed to be consumed by the CPU is reduced. For example, when an operational frequency of the CPU is reduced in order to reduce power to be consumed by the CPU in response to the execution of a task by the FPGA, the processing power of the CPU is reduced.

According to an aspect, an object of the present disclosure is to suppress a reduction, depending on a task executed by a reconfiguring section installed together with a controller in a semiconductor device, in the processing power of the controller.

Embodiments are described with reference to the accompanying drawings.

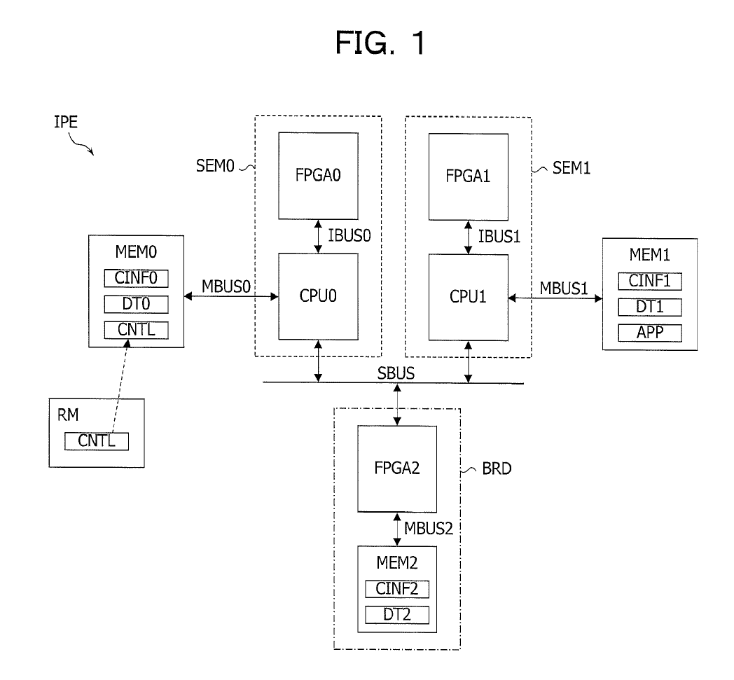

FIG. 1 illustrates an embodiment of an information processing device, a method for controlling the information processing device, and a control program of the information processing device. The information processing device IPE illustrated in FIG. 1 includes a plurality of semiconductor devices SEM (SEM0 and SEM1), a plurality of storage devices MEM (MEM0 and MEM1), and a board BRD. The information processing device IPE may include three or more semiconductor devices SEM and two or more boards BRD.

For example, the semiconductor devices SEM0 and SEM1 and the storage devices MEM0 and MEM1 are mounted on a motherboard (not illustrated) of the information processing device IPE. The board BRD is attached to a socket mounted on the motherboard. For example, the storage devices MEM0 and MEM1 are dual inline memory modules (DIMMs), each of which includes a plurality of synchronous dynamic random access memories (SDRAMs).

The semiconductor device SEM0 includes a central processing unit CPU0 (hereinafter merely referred to as CPU0) and a field-programmable gate array FPGA0 (hereinafter merely referred to as FPGA0) that are connected to each other via an internal bus IBUS0, while the semiconductor device SEM1 includes a central processing unit CPU1 (hereinafter merely referred to as CPU1) and a field-programmable gate array FPGA1 (hereinafter merely referred to as FPGA1) that are connected to each other via an internal bus IBUS1. Another processor may be mounted on the motherboard, instead of the CPU0 and the CPU1. Another programmable device that reconfigures logic may be mounted on the motherboard, instead of the FPGA0 and the FPGA1.

For example, the semiconductor device SEM0 (or SEM1) is a multi-chip module (multi-chip package) that has a semiconductor chip including the CPU0 (or the CPU1) and has a semiconductor chip including the FPGA0 (or the FPGA1). If the semiconductor chips are stacked in the multi-chip module, the semiconductor chips are connected to each other via a through-electrode such as a through-silicon via (TSV).

Alternatively, the semiconductor device SEM0 (or SEM1) has a semiconductor chip that is a system-on-a-chip (SoC) or the like and includes the CPU0 (or the CPU1) and the FPGA0 (or the FPGA1). In this case, the FPGA0 (or the FPGA1) may be included in the CPU0 (or the CPU1), or the CPU0 (or the CPU1) may be included in the FPGA0 (or the FPGA1).

Since the semiconductor device SEM0 has an upper limit on power to be consumed by the semiconductor device SEM0, the total of power consumed by the CPU0 and power consumed by the FPGA0 is limited to a value equal to or lower than the upper limit of the semiconductor device SEM0. Similarly, since the semiconductor device SEM1 has an upper limit on power to be consumed by the semiconductor device SEM1, the total of power consumed by the CPU1 and power consumed by the FPGA1 is limited to a value equal to or lower than the upper limit of the semiconductor device SEM1. For example, the upper limits of the semiconductor devices SEM0 and SEM1 are 130 W.

The storage device MEM0 is connected to the CPU0 via a memory bus MBUS0, while the storage device MEM1 is connected to the CPU1 via a memory bus MBUS1. The CPU0 and the CPU1 are connected to each other via a system bus SBUS. For example, the system bus SBUS is a Peripheral Component Interconnect Express (PCIe) bus. Each of the CPU0 and the CPU1 is an example of a controller configured to control the execution of a task, while each of the FPGA0 and the FPGA1 is an example of a first reconfiguring section configured to reconfigure logic for executing the task.

The CPU0 accesses the storage device MEM1 via the system bus SBUS and the CPU1. The CPU1 accesses the storage device MEM0 via the system bus SBUS and the CPU0. Specifically, the information processing device IPE functions as a multi-processor system with cache-coherent nonuniform memory access (NUMA) architecture.

The storage device MEM0 includes a region for storing circuit information CINF0 corresponding to logic (circuit) programmed in the FPGA0 and a region for storing data DT0 and the like that are used for a task executed by the logic programmed in the FPGA0. In addition, the storage device MEM0 has a region for storing the control program CNTL to be executed by the CPU0. The CPU0 that executes the control program CNTL is an example of a first controller. The semiconductor device SEM0, which includes the CPU0 that executes the control program CNTL, is an example of a first semiconductor device.

The control program CNTL may be stored in a computer-readable recording medium RM such as a compact disc read only memory (CD-ROM), a digital versatile disc (DVD), or a Universal Serial Bus (USB) memory. In this case, the control program CNTL stored in the recording medium RM is transferred to the storage device MEM0 from the recording medium RM via an input and output interface (not illustrated) included in the information processing device IPE. The control program CNTL may be transferred from the recording medium RM to a hard disk drive (HDD) (not illustrated) and transferred from the HDD to the storage device MEM0. The control program CNTL may be stored in the storage device MEM1. When the control program CNTL is executed by the CPU1, the CPU1 functions as the first controller.

The storage device MEM1 has a region for storing circuit information CINF1 corresponding to logic programmed in the FPGA1 and a region for storing data DT1 and the like that are used for a task executed by the logic programmed in the FPGA1. In addition, the storage device MEM1 has a region for storing an application program APP to be executed by the CPU0 or the CPU1. The application program APP may be stored in the storage device MEM0.

The board BRD includes a field-programmable gate array FPGA2 (hereinafter merely referred to as FPGA2) and a storage device MEM2 that are connected to each other via a memory bus MBUS2. The storage device MEM2 is an SDRAM or the like. The FPGA2 is connected to the system bus SBUS. The FPGA2 is connected to the semiconductor devices SEM0 and SEM1 and is an example of a second reconfiguring section configured to reconfigure logic for executing a task. The FPGA2 may be a discrete field-programmable gate array. An upper limit on power to be consumed by the FPGA2 depends on an upper limit on power to be consumed by the board BRD and is sufficiently larger than the upper limits of the semiconductor devices SEM0 and SEM1. In addition, power consumed by the board BRD in a standby state is larger than power consumed by each of the semiconductor devices SEM0 and SEM1 in standby states.

The storage device MEM2 has a region for storing circuit information CINF2 corresponding to logic programmed in the FPGA2 and a region for storing data DT2 and the like that are used for a task executed by the logic programmed in the FPGA2.

The widths of the internal buses IBUS0 and IBUS1 are larger than the width of the system bus SBUS, while the lengths of the internal buses IBUS0 and IBUS1 are smaller than the length of the system bus SBUS. Thus, data transfer rates of the internal buses IBUS0 and IBUS1 are higher than a data transfer rate of the system bus SBUS. For example, the data transfer rates of the internal buses IBUS0 and IBUS1 are equal to each other.

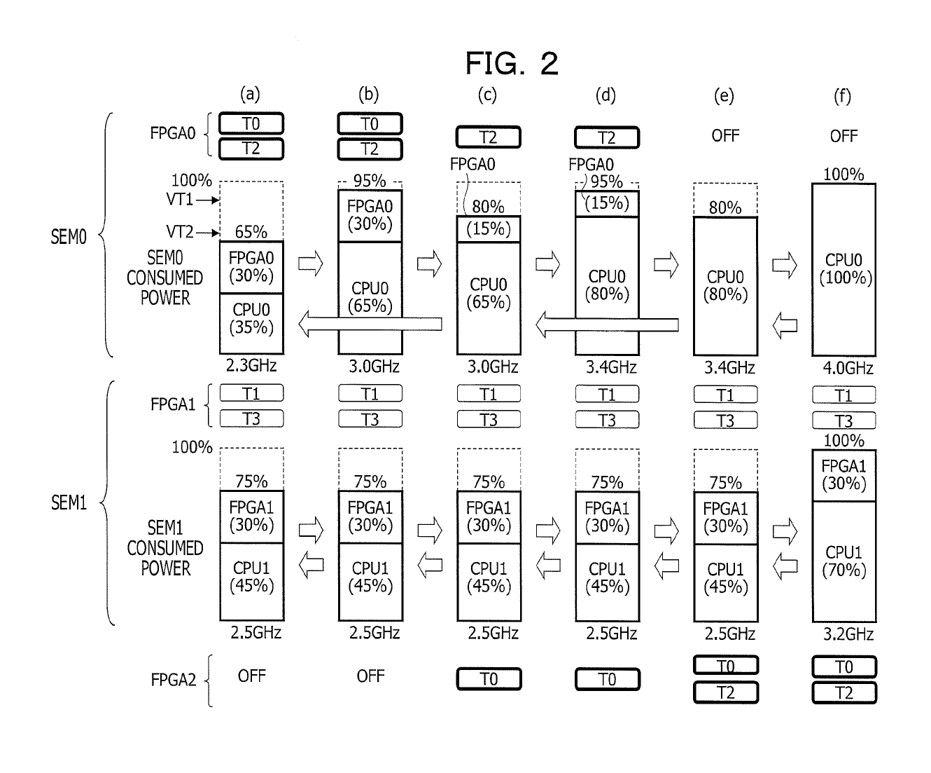

FIG. 2 illustrates an example of operations of the information processing device IPE illustrated in FIG. 1. In other words, FIG. 2 illustrates an example of a method for controlling the information processing device IPE. Values illustrated in FIG. 2 are an example and may be other values. The information processing device IPE executes the application program APP, thereby causing the CPUs (CPU0 and CPU1) to execute multiple processes and causing an FPGA (FPGA0, FPGA1, or FPGA2) to execute different tasks T0, T1, T2, and T3.

The information processing device IPE causes the corresponding FPGA to operate as an accelerator and execute data processing such as image processing, arithmetic processing, or statistical processing, for example. In addition, the information processing device IPE causes any of the CPUs to execute the control program CNTL, thereby executing control to switch the FPGA for executing the tasks T (T0, T1, T2, and T3). An example in which the CPU0 executes the control program CNTL is described below.

The information processing device IPE executes dynamic frequency scaling (DFS) control to change operational frequencies of the CPUs based on operational states of the CPUs. The information processing device IPE may execute dynamic voltage and frequency scaling (DVFS) control to change the operational frequencies and power-supply voltages of the CPUs based on the operational states of the CPUs. For example, the control program CNTL acquires, via a baseboard management controller (BMC) mounted on the motherboard of the information processing device IPE, information indicating power consumed by the semiconductor device SEM0. The BMC manages the operational frequencies of the CPUs, the power-supply voltages of the CPUs, operational states of the storage devices MEM, an operational state of a cooling fan attached to a housing of the information processing device IPE, and the like.

In an example illustrated in FIG. 2, a data transfer cost for the task T3 is largest, followed in order by data transfer costs for the tasks T1, T2, and T0. If the tasks T0 to T3 are executed by a single FPGA (FPGA0, FPGA1, or FPGA2), the data transfer costs are costs for data transfer between the FPGA and a CPU for the tasks T0 to T3. Specifically, the data transfer cost for the task T0 is smallest, while the data transfer cost for the task T3 is largest. In the example illustrated in FIG. 2, the tasks T0 and T2 for which the data transfer costs are relatively small are indicated by thick frames. As a data transfer cost for a task increases, a time period for data transfer between the CPU and the FPGA for the task increases and processing power for the task is reduced.

As the amount of data transferred between a CPU and an FPGA in response to the execution of a task increases, a data transfer cost for the task increases. As the number of times of data transfer between a CPU and an FPGA in response to the execution of a task increases, a data transfer cost for the task increases. As a data transfer rate between a CPU and an FPGA for a task is reduced, a data transfer cost for the task increases. Data to be transferred between a CPU and an FPGA includes data to be processed for a task T to be executed by the FPGA and data obtained by the processing.

For example, the data transfer cost for the tasks T are calculated as time periods tD (seconds) for the data transfer between the CPUs and the FPGAs in response to the execution of the tasks T within a predetermined time period P (of, for example, 10 seconds). The data transfer time periods tD are calculated according to Equation (1). In Equation (1), a symbol D indicates amounts of data to be transferred within the predetermined time period P, and a symbol S indicates data transfer rates (MB per second) between the CPUs and FPGAs included in the semiconductor devices SEM. A symbol K indicates the numbers of times of the data transfer to be executed within the predetermined time period P, and a symbol A indicates overhead (seconds) to be taken for data transfer executed once. The overhead is time to be taken for an interruption process executed by a CPU and the like in the case where data is transferred between the CPU and an FPGA. The overhead is, for example, several tens of milliseconds.

tD=(D/S)+(K×A) (1)

If the amount of data to be transferred between a CPU and a task T to be processed by an FPGA, and the frequency at which the task T is executed, are known in advance, the information processing device IPE may calculate a time period tD for the data transfer before the start of the execution of the task T. In addition, the information processing device IPE may program, in an arbitrary FPGA, logic for executing tasks T of multiple types, cause the FPGA to execute the tasks T, and measure the time periods tD for the data transfer executed within the predetermined time period P.

In the example illustrated in FIG. 2, the data transfer time periods tD are calculated before the start of the execution of the tasks T, and it is determined that the data transfer cost for the task T3 is largest, followed in order by the data transfer costs for the tasks T1, T2, and T0. Logic for executing the tasks T0 and T2 for which the data transfer costs are relatively small is programmed in the FPGA0, while logic for executing the tasks T1 and T3 for which the data transfer costs are relatively large is programmed in the FPGA1. FIGS. 2A to 2F illustrate the example of the operations in the case where data processing is not executed by the FPGAs and where the amount D of data to be transferred for each of the tasks T within the predetermined time period P and the number K of times of data transfer to be executed for each of the tasks T within the predetermined time period P are estimated.

The programming of the logic in the FPGA0 is executed by the CPU0 that executes the control program CNTL, while the programming of the logic in the FPGA1 is executed by the CPU1 in accordance with an instruction from the CPU0 that executes the control program CNTL. Since a task T to be executed by the FPGA2 does not exist, the control program CNTL executed by the CPU0 sets the FPGA2 to a power down state OFF. In addition, since the FPGA2 does not operate, the control program CNTL executed by the CPU0 sets the storage device MEM2 used as a work memory of the FPGA2 to a power down state OFF.

For example, in the FPGA2 in the power down state OFF, power is supplied only to a command (packet) receiver connected to the system bus SBUS in order to set the FPGA2 to a packet reception waiting state, and the supply of power to other elements is blocked. For example, the supply of power to the storage device MEM2 in the power down state OFF is blocked. If a task T to be executed by the FPGA2 does not exist, power to be consumed by the information processing device IPE may be reduced by setting the FPGA2 and the storage device MEM2 to the power down states OFF, compared with the case where the FPGA2 and the storage device MEM2 are not set to the power down states OFF.

The data transfer costs in the case where data is transferred between the CPU0 and the FPGA0 are smaller than the data transfer costs in the case where data is transferred between the CPU0 and the FPGA2. Similarly, the data transfer costs in the case where data is transferred between the CPU1 and the FPGA1 are smaller than the data transfer costs in the case where data is transferred between the CPU1 and the FPGA2. This is due to the fact that the data transfer rate of the system bus SBUS illustrated in FIG. 1 is lower than the data transfer rates of the internal buses IBUS0 and IBUS1 and that as the data transfer rates S are reduced, the data transfer time periods tD increase according to Equation (1).

As illustrated in a state (a) of FIG. 2, power consumed by the FPGA0 executing the tasks T0 and T2 based on an instruction of the application program APP is 30% of the upper limit (100%) on power to be consumed by the semiconductor device SEM0. Power consumed by the CPU0 executing a process due to the application program APP is 35% of the upper limit on power to be consumed by the semiconductor device SEM0, and an operational frequency of the CPU0 is 2.3 GHz. Thus, power consumed by the semiconductor device SEM0 is 65% of the upper limit.

Power consumed by the FPGA1 executing the tasks T1 and T3 based on an instruction of the application program APP is 30% of an upper limit on power to be consumed by the semiconductor device SEM1. Power consumed by the CPU1 executing a process due to the application program APP is 45% of the upper limit on power to be consumed by the semiconductor device SEM1, and an operational frequency of the CPU1 is 2.5 GHz. Thus, power consumed by the semiconductor device SEM1 is 75% of the upper limit.

FIG. 2 illustrates the example in which power consumed by the semiconductor device SEM1 does not change in order to clarify the description. The power consumed by the semiconductor device SEM1, however, may change due to an increase or reduction in a load applied to the CPU1. The control program CNTL executed by the CPU0 does not execute a process of switching a task T between the FPGA1 and the FPGA2 based on thresholds VT1 and VT2 described later. For example, the application program APP may control a process of applying a load to the CPU1 in such a manner that power consumed by the semiconductor device SEM1 is maintained at 90% of the upper limit.

Next, as illustrated in a state (b) of FIG. 2, the number of processes assigned to the CPU0 increases due to the execution of the application program APP, and the operational frequency of the CPU0 increases to 3.0 GHz. Power consumed by the CPU0 becomes 65% of the upper limit, and power consumed by the semiconductor device SEM0 becomes 95% of the upper limit.

If power consumed by the semiconductor device SEM0 exceeds the threshold VT1 (of, for example, 90% of the upper limit), the control program CNTL executes a process of programming, in the FPGA2, any type of the logic programmed in the FPGA0, as illustrated in a state (c) of FIG. 2. For example, tasks for which logic is to be migrated from the FPGA0 to the FPGA2 are determined in ascending order of data transfer cost (or in ascending order of data transfer time period tD). During the time when the task T0 is not executed, the CPU0 programs, in the FPGA2, the logic for executing the task T0. Then, the CPU0 causes the FPGA2 to execute the task T0. The threshold VT1 is an example of a first predetermined value.

In the state (c) of FIG. 2, since the FPGA0 does not execute the task T0, power consumed by the FPGA0 is 15% of the upper limit on power to be consumed by the semiconductor device SEM0. Thus, power consumed by the semiconductor device SEM0 becomes 80% of the upper limit.

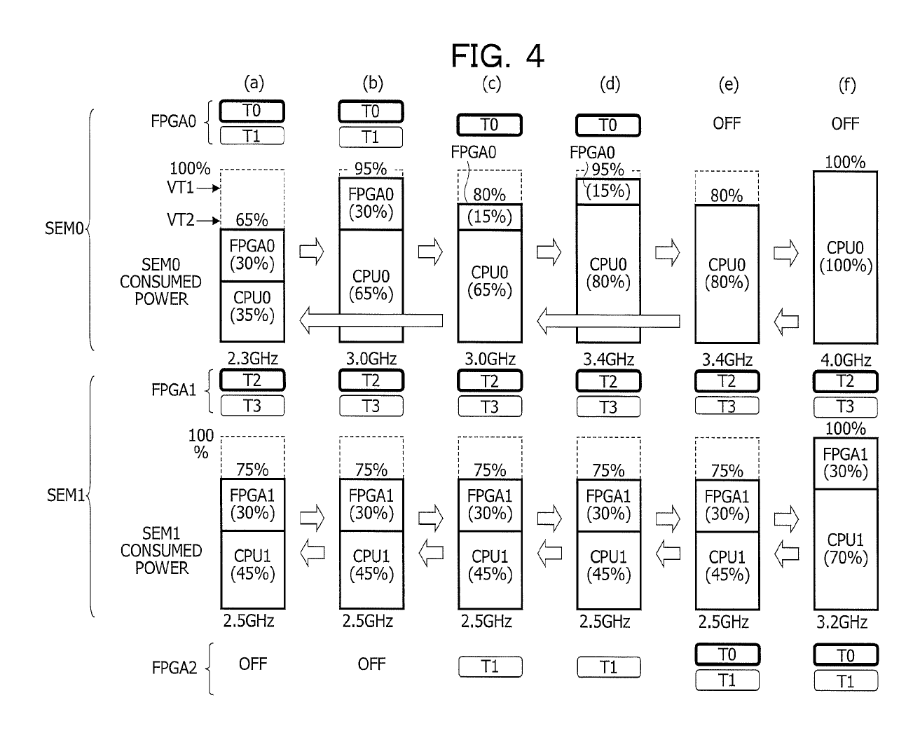

However, if the FPGA2 executes the task T0, the semiconductor device SEM0 may have a margin of 20% with respect to the upper limit on power to be consumed by the semiconductor device SEM0, and the CPU0 may have a margin in processing power. If power consumed by the semiconductor device SEM0 exceeds the threshold VT1, logic for a task T executed by the FPGA0 is migrated from the FPGA0 to the FPGA2, and the CPU0 may have a margin with respect to the upper limit on power to be consumed by the semiconductor device SEM0, and the CPU0 may have a margin in processing power. In addition, by selectively migrating, from the FPGA0 to the FPGA2, logic for executing a task T for which a data transfer cost is relatively small, an effect of an increase in a time period for data transfer between the FPGA2 and the CPU0 for the task T migrated to the FPGA2 may be reduced and a reduction in processing power for the task T may be suppressed to the minimum level. As a result, the performance of the information processing device IPE may be improved. An example of operations in the case where a task T for which a data transfer cost applied to the CPU0 is relatively small is migrated from the FPGA0 to the FPGA2 is described later with reference to FIGS. 4A to 4F.

Next, as illustrated in a state (d) of FIG. 2, the number of processes assigned to the CPU0 increases and the operational frequency of the CPU0 increases to 3.4 GHz. Power consumed by the CPU0 becomes 80% of the upper limit on power to be consumed by the semiconductor device SEM0, and power consumed by the semiconductor device SEM0 becomes 95% of the upper limit.

Since power consumed by the semiconductor device SEM0 exceeds the threshold VT1, the control program CNTL executes a process of programming, in the FPGA2, the logic for executing the task T2, as illustrated a state (e) in FIG. 2. For example, during the time when the task T2 is not executed, the CPU0 programs, in the FPGA2, the logic for executing the task T2. Then, the CPU0 causes the FPGA2 to execute the tasks T0 and T2. Every time power consumed by the semiconductor device SEM0 exceeds the threshold VT1, the CPU0 programs, in the FPGA2, logic for a task T executed by the FPGA0. Thus, the CPU0 may migrate the minimum logic to the FPGA2 based on a change in power consumed by the semiconductor device SEM0. If a task T is executable by the FPGA0 and the FPGA2, the FPGA0 executes the task T as much as possible, data transfer to the FPGA2 that takes more time than data transfer to the FPGA0 may be reduced, and a reduction in the performance of the information processing device IPE may be suppressed.

Since a task T to be executed by the FPGA0 does not exist, the control program CNTL sets the FPGA0 to a power down state OFF. Since power consumed by the FPGA0 in the power down state OFF is only power consumed for waiting for reception of a command (packet), like the FPGA2 in the power down state OFF, the FPGA0 in the power down state OFF hardly consumes power. Thus, power consumed by the semiconductor device SEM0 becomes 80% of the upper limit. If a task T to be executed by the FPGA0 does not exist, power to be consumed by the information processing device IPE may be reduced by setting the FPGA0 to the power down state OFF, compared with the case where the FPGA0 is not set to the power down state OFF.

Next, as illustrated in a state (f) of FIG. 2, the number of processes assigned to the CPU0 increases and the operational frequency of the CPU0 increases to 4.0 GHz. The maximum operational frequencies of the CPU0 and the CPU1 are 4.0 GHz, but are not limited to this. Specifically, power consumed by the CPU0 and power consumed by the semiconductor device SEM0 become equal to the upper limit on power to be consumed by the semiconductor device SEM0. The migration of the logic for the tasks T executed by the FPGA0 to the FPGA2 may cause almost all power consumed by the semiconductor device SEM0 to contribute to an operation of the CPU0 and may maximize the processing power of the CPU0.

In the state (f) of FIG. 2, the number of processes assigned to the CPU1 increases, the operational frequency of the CPU1 increases to 3.2 GHz, and power consumed by the CPU1 becomes 70% of the upper limit on power to be consumed by the semiconductor device SEM1. Power consumed by the semiconductor device SEM1 becomes equal to the upper limit. In this state, the total of the operational frequencies of the CPU0 and the CPU1 is 7.2 GHz.

If the number of processes assigned to the CPU0 is reduced in the state (f) of FIG. 2, the state of the information processing device IPE changes from the state (f) of FIG. 2 to the state (e) of FIG. 2. If the number of processes assigned to the CPU0 is further reduced and power consumed by the semiconductor device SEM0 becomes equal to or lower than the threshold VT2 (of, for example, 70%), the CPU0 reprograms, in the FPGA0, the logic for executing the task T2. For example, tasks to be migrated from the FPGA2 to the FPGA0 are determined in descending order of data transfer cost (or in descending order of data transfer time period tD). Then, the CPU0 causes the FPGA0 to execute the task T2 that has been executed by the FPGA2. The threshold VT2 is an example of a second predetermined value. For example, the state of the information processing device IPE changes to the state (c) of FIG. 2. If power consumed by the semiconductor device SEM0 becomes equal to or lower than the threshold VT2, the CPU0 may cause the FPGA2 to execute the minimum task T0 by programming, in the FPGA0, the logic for the task T2 executed by the FPGA2. In addition, a process of transferring data between the CPU0 and the task T2 may be improved by migrating the logic for executing the task T2 from the FPGA2 to the FPGA0, and a reduction in the performance of the information processing device IPE may be suppressed.

In the state (c) of FIG. 2, if the number of processes assigned to the CPU0 is reduced and power consumed by the semiconductor device SEM0 becomes equal to or lower than the threshold VT2 again, the CPU0 reprograms, in the FPGA0, the logic for executing the task T0. Then, the CPU0 causes the FPGA0 to execute the task T0 that has been executed by the FPGA2. For example, the state of the information processing device IPE changes to the state (a) of FIG. 2. After that, in response to the change in the number of processes assigned to the CPU0, power consumed by the CPU0 changes and the state of the information processing device IPE changes between the state (a) of FIG. 2 and the state (f) of FIG. 2.

Every time power consumed by the semiconductor device SEM0 becomes equal to or lower than the threshold VT2, the CPU0 may cause the FPGA2 to execute the minimum task T by programming, in the FPGA0, a task T executed by the FPGA2. This may minimize a load to be applied to the CPU0 due to data transfer between the CPU0 and the FPGA2 and suppress a reduction in the performance of the information processing device IPE.

In order to suppress frequent repetition of switching between the FPGA0 and the FPGA2 for the execution of a task T, it is preferable the difference between the thresholds VT1 and VT2 be larger than the maximum power consumed for a task T executed by the FPGA0 among power consumed for various types of tasks T executed by the FPGA0. In addition, in order to migrate a task T from the FPGA2 to the FPGA0, it is preferable that the difference between the maximum value of power consumed by the semiconductor device SEM0 and the threshold VT2 be larger than the maximum power consumed for the task T executed by the FPGA0 among the power consumed for the various types of the tasks T executed by the FPGA0.

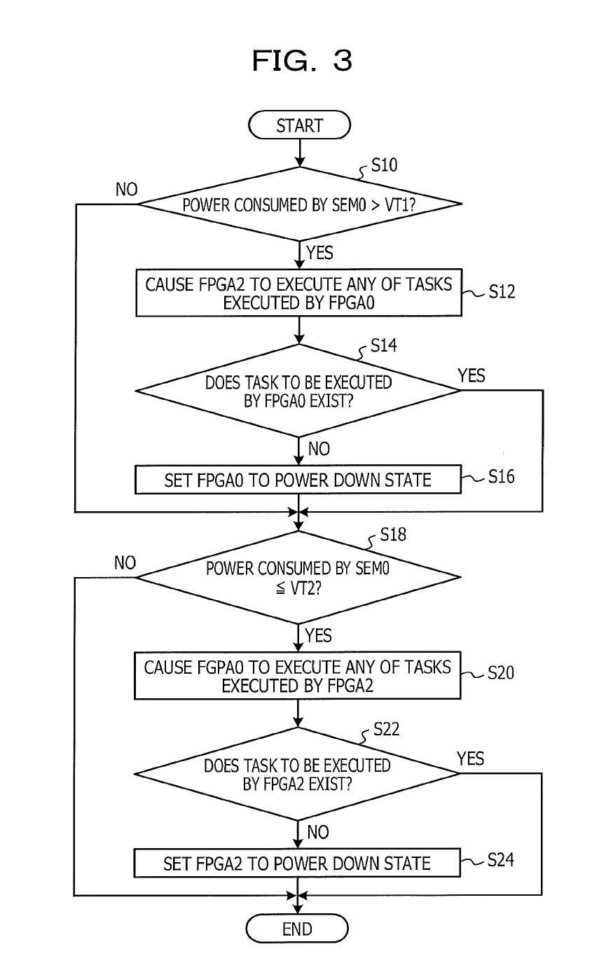

FIG. 3 illustrates an example of a process of the control program CNTL executed by the CPU0 illustrated in FIG. 1. The process illustrated in FIG. 3 is repeatedly executed at a predetermined frequency.

First, in step S10, the CPU0 determines whether or not power consumed by the semiconductor device SEM0 has exceeded the threshold VT1. If the consumed power has exceeded the threshold VT1, the process proceeds to step S12. If the consumed power has not exceeded or is equal to or lower than the threshold VT1, the process proceeds to step S18. If logic is not programmed in the FPGA0, and a task T to be executed by the FPGA0 does not exist, the process proceeds to step S18.

In step S12, the CPU0 programs, in the FPGA2, any type of logic programmed in the FPGA0 and causes the FPGA2 to execute any of tasks T executed by the FPGA0. In this case, it is preferable that tasks for which logic is to be migrated from the FPGA0 to the FPGA2 be determined in ascending order of data transfer cost, as described with reference to FIGS. 2A to 2F. Next, in step S14, the CPU0 determines whether or not a task T to be executed by the FPGA0 exists. If the task T to be executed by the FPGA0 exists, the process proceeds to step S18. If the task T to be executed by the FPGA0 does not exist, the process proceeds to step S16.

In step S16, the CPU0 sets the FPGA0 to the power down state OFF. After step S16, the process proceeds to step S18. In step S18, the CPU0 determines whether or not power consumed by the semiconductor device SEM0 is equal to or lower than the threshold VT2. If the power consumed by the semiconductor device SEM0 is equal to or lower than the threshold VT2, the process proceeds to step S20. If the power consumed by the semiconductor device SEM0 exceeds the threshold VT2, the process is terminated. If logic is not programmed in the FPGA2, and a task T to be executed by the FPGA2 does not exist, the process is terminated.

In step S20, the CPU0 programs, in the FPGA0, any type of logic programmed in the FPGA2 and causes the FPGA0 to execute any of tasks T executed by the FPGA2. In this case, as described with reference to FIGS. 2A to 2F, it is preferable that tasks for which logic is to be migrated from the FPGA2 to the FPGA0 be determined in descending order of data transfer cost. Then, in step S22, the CPU0 determines whether or not a task T to be executed by the FPGA2 exists. If the task T to be executed by the FPGA2 exists, the process proceeds to step S24. If the task T to be executed by the FPGA2 does not exist, the process is terminated.

FIG. 4 illustrates another example of operations of the information processing device IPE illustrated in FIG. 1. A detailed description of operations that are the same as or similar to those described with reference to FIG. 2 is omitted. In a state (a) and a state (b) of FIG. 4, the logic for executing the tasks T0 and T1 is programmed in the FPGA0, and the logic for executing the tasks T2 and T3 is programmed in the FPGA1. Specifically, the control program CNTL executed by the CPU0 does not execute a process of determining, based on the data transfer costs, FPGAs in which the logic for executing the tasks T0 to T3 is to be programmed. For example, a load applied to the CPU0 in the case where the FPGA0 executes the tasks T0 and T1 is equal to or nearly equal to a load applied to the CPU1 in the case where the FPGA1 executes the tasks T2 and T3.

In the state (a) of FIG. 4, power consumed by the FPGA0 executing the tasks T0 and T1 is 30% of the upper limit on power to be consumed by the semiconductor device SEM0, and power consumed by the FPGA1 executing the tasks T2 and T3 is 30% of the upper limit on power to be consumed by the semiconductor device SEM1. Power consumed by the CPU0 executing a process is 35% of the upper limit on power to be consumed by the semiconductor device SEM0, and the operational frequency of the CPU0 is 2.3 GHz. Power consumed by the semiconductor device SEM0 is 65% of the upper limit. Power consumed by the CPU1 executing a process is 45% of the upper limit on power to be consumed by the semiconductor device SEM1, and the operational frequency of the CPU1 is 2.5 GHz. Power consumed by the semiconductor device SEM1 is 75% of the upper limit. The following description assumes that power consumed by the semiconductor device SEM1 does not change in order to clarify the description.

Next, as illustrated in the state (b) of FIG. 4, if the number of processes assigned to the CPU0 increases and power consumed by the semiconductor device SEM0 exceeds the threshold VT1, the CPU0 executes a process of programming, in the FPGA2, the logic for executing the task T1, as illustrated in FIG. 4C. The logic for executing the task T0 may be migrated from the FPGA0 to the FPGA2, instead of the logic for executing the task T1.

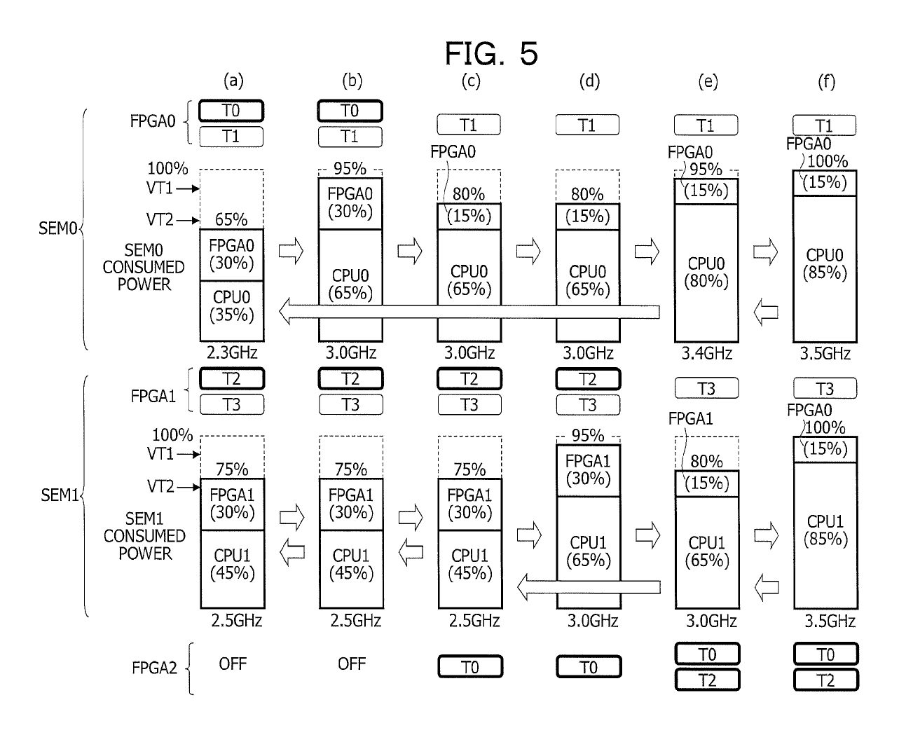

In a state (c) of FIG. 4, since the FPGA0 executes only the task T0, power consumed by the FPGA0 becomes 15% of the upper limit on power to be consumed by the semiconductor device SEM0. Power consumed by the CPU0, the operational frequency of the CPU0, and power consumed by the semiconductor device SEM0 are equal to those illustrated in the state (c) of FIG. 2. However, if the task T1 for which the data transfer cost is higher than that of the task T0 is executed by the FPGA2, the total processing power of the semiconductor device SEM0 is reduced, compared with the case where the task T0 is executed by the FPGA2. In other words, the processing power of the semiconductor device SEM0 in the case where the task T0 is executed by the FPGA0 and the task T1 is executed by the FPGA2 is lower than the processing power of the semiconductor device SEM0 in the case where the task T1 is executed by the FPGA0 and the task T0 is executed by the FPGA2. For example, the processing power of the semiconductor device SEM0 in the state (c) of FIG. 4 is lower than the processing power of the semiconductor device SEM0 in a state (c) of FIG. 5 described later.

Operations indicated in a state (d) of FIG. 4 are the same as the operations indicated in the state (d) of FIG. 2, except that tasks to be executed by the FPGA1 and the FPGA2 in the state (d) of FIG. 4 are different from the tasks executed by the FPGA1 and the FPGA2 in the state (d) of FIG. 2. Operations indicated in a state (e) of FIG. 4 are the same as the operations indicated in the state (e) of FIG. 2. Operations indicated in a state (f) of FIG. 4 are the same as the operations indicated in the state (f) of FIG. 2.

FIG. 5 illustrates still another example of operations of the information processing device IPE illustrated in FIG. 1. A detailed description of operations that are the same as or similar to those described with reference to FIGS. 2 and 4 is omitted. Operations indicated in a state (a) and a state (b) of FIG. 5 are the same as the operations indicated in the state (a) and the state (b) of FIG. 4. Specifically, the logic for executing the tasks T0 and T1 is programmed in the FPGA0, and the logic for executing the tasks T2 and T3 is programmed in the FPGA1.

In the example illustrated in FIG. 5, the process of determining, based on the data transfer costs, FPGAs in which the logic for executing the tasks T0 to T3 is to be programmed is not executed, like the example illustrated in FIG. 4. In the example illustrated in FIG. 5, the control program CNTL executes control to switch the FPGA0 and the FPGA1 to the FPGA2 for the tasks T0 and T2 so as to cause the FPGA2 to execute the tasks T0 and T2 for which the data transfer costs are relatively low. The control program CNTL is executed by the CPU0, but may be executed by the CPU1.

As illustrated in the state (b) of FIG. 5, if the number of processes assigned to the CPU0 increases and power consumed by the semiconductor device SEM0 exceeds the threshold VT1, the CPU0 executes a process of programming, in the FPGA2, the logic for executing the task T0, as illustrated in a state (c) of FIG. 5. Specifically, the CPU0 causes the FPGA2 to execute the task T0 for which the data transfer cost is lower than that of the task T1.

Next, in a state (d) of FIG. 5, the number of processes assigned to the CPU1 increases and power consumed by the semiconductor device SEM1 exceeds the threshold VT1. The control program CNTL executed by the CPU0 executes the process of programming, in the FPGA2, the logic for executing the task T2, as illustrated in a state (e) of FIG. 5. Specifically, the control program CNTL causes the FPGA2 to execute the task T2 for which the data transfer cost is lower than that of the task T3. Since the FPGA1 executes only the task T3, power consumed by the FPGA1 is 15% of the upper limit on power to be consumed by the semiconductor device SEM1.

In the state (e) of FIG. 5, the number of processes assigned to the CPU0 increases, the operational frequency of the CPU0 increases to 3.4 GHz, and power consumed by the semiconductor device SEM0 becomes 95% of the upper limit. In a state (f) of FIG. 5, the number of processes assigned to the CPU0 further increases, the operational frequency of the CPU0 increases to 3.5 GHz, and power consumed by the semiconductor device SEM0 becomes equal to the upper limit (or 100% of the upper limit). In addition, the number of processes assigned to the CPU1 increases, the operational frequency of the CPU1 increases to 3.5 GHz, and power consumed by the semiconductor device SEM1 becomes equal to the upper limit.

In the state (f) of FIG. 5, since the FPGA0 executes the task T1, the FPGA1 executes the task T3, and the FPGA2 executes the tasks T0 and T2, all the FPGA1, FPGA2, and FPGA3 consume power. Since power consumed by the semiconductor device SEM0 includes power consumed by the FPGA0, the operational frequency of the CPU0 is set to 85% of the maximum operational frequency (of 4.0 GHz). Similarly, since power consumed by the semiconductor device SEM1 includes power consumed by the FPGA1, the operational frequency of the CPU1 is set to 85% of the maximum operational frequency (of 4.0 GHz). The total of the operational frequencies of the CPU0 and CPU1 in the state (f) of FIG. 5 is 7.0 GHz and lower than the total (7.2 GHz) of the operational frequencies of the CPU0 and CPU1 in the state (f) of FIG. 4. In other words, both CPU0 and CPU1 do not operate at the maximum operational frequency, regardless of the fact that the control program CNTL causes the FPGA2 to execute the tasks T0 and T2. Thus, the total performance of the information processing device IPE that includes the processing power and power performance of the information processing device IPE in the state (f) of FIG. 5 is lower than that in the state (f) of FIG. 4.

In order to improve the total performance of the information processing device IPE, the logic, programmed in the FPGA0, for executing the task T1 may be programmed in the FPGA1, and the state of the information processing device IPE may change from the state (f) of FIG. 5 to the state (f) of FIG. 4. In this case, however, it takes to reconfigure the logic, and the processing power of the information processing device IPE is reduced during the reconfiguration of the logic.

In the embodiment described with reference to FIGS. 1 to 5, the tasks T0 and T2 for which the data transfer costs are relatively small are executed by the FPGA0, and the tasks T1 and T3 for which the data transfer costs are relatively large are executed by the FPGA2. If power consumed by the semiconductor device SEM0 exceeds the threshold VT1, the control program CNTL programs, in the FPGA2, any type of logic for tasks T executed by the FPGA0. Thus, an increase in processing time for data transfer between the FPGA0 and the FPGA2 may be minimized and the performance of the information processing device IPE may be improved. Specifically, a reduction in the processing power of the CPU0 that depends on tasks T executed by the FPGA0 included together with the CPU0 in the semiconductor device SEM0 may be suppressed.

By programming, in the FPGA2, logic for a task T executed by the FGPA0 every time power consumed by the semiconductor device SEM0 exceeds the threshold VT1, the minimum task T may be executed by the FPGA2. Thus, an increase in a time period for data transfer between the CPU0 and the FPGA2 may be suppressed and a reduction in the performance of the information processing device IPE may be suppressed.

If power consumed by the semiconductor device SEM0 becomes equal to or lower than the threshold VT2, the control program CNTL may cause the FPGA2 to execute the minimum task T by programming, in the FGPA0, logic for a task executed by the FPGA2. Thus, data transfer processing between the CPU0 and the task T0 may be improved and a reduction in the performance of the information processing device IPE may be suppressed. In addition, by programming, in the FPGA0, logic for a task T executed by the FPGA2 every time power consumed by the semiconductor device SEM0 becomes equal to or lower than the threshold VT2, an increase in a time period for data transfer between the CPU0 and the FPGA2 may be minimized.

If a task T to be executed by the FPGA0 does not exist, power to be consumed by the information processing device IPE may be reduced by setting the FPGA0 to the power down state OFF, compared with the case where the FPGA0 is not set to the power down state OFF. If a task T to be executed by the FPGA2 does not exist, power to be consumed by the information processing device IPE may be reduced by setting the FPGA2 and the storage device MEM2 to the power down states OFF, compared with the case where the FPGA2 and the storage device MEM2 are not set to the power down states OFF.

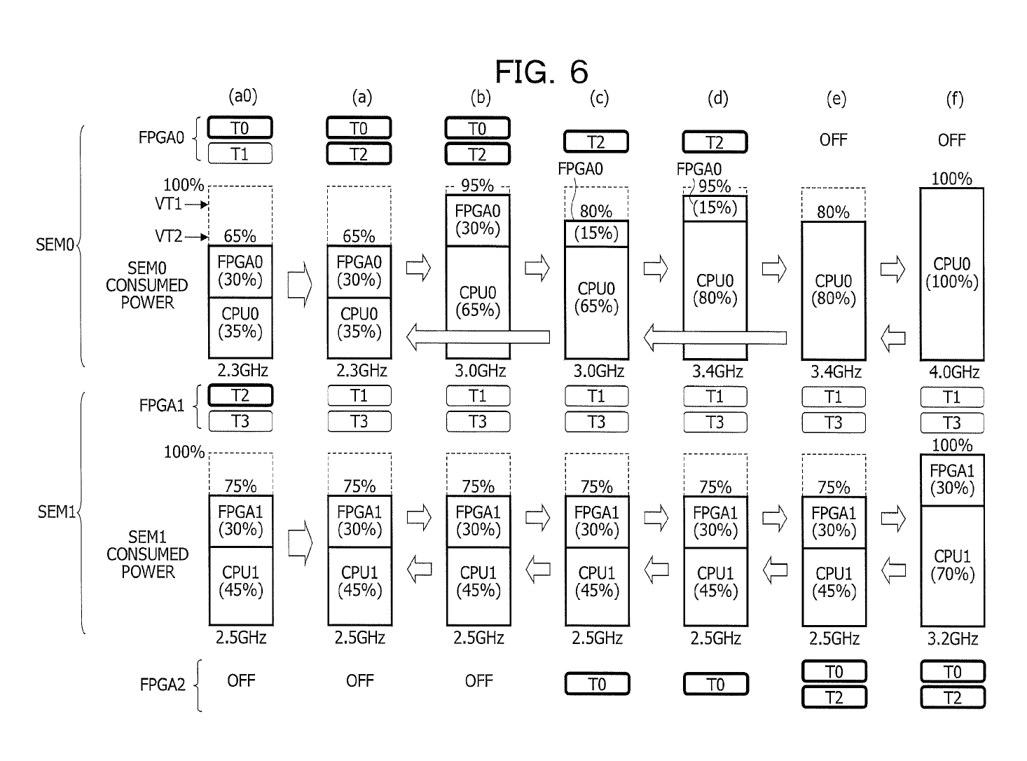

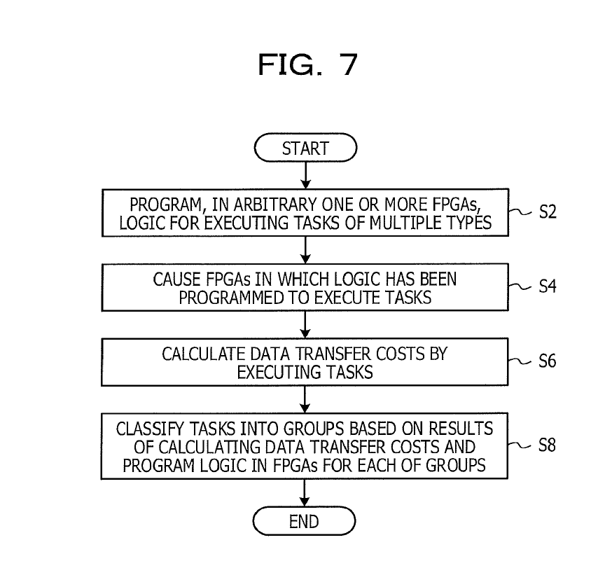

FIG. 6 illustrates an example of operations of an information processing device according to another embodiment. A detailed description of operations that are the same as or similar to those described with reference to FIG. 2 is omitted. The information processing device that executes the operations indicated in FIG. 6 has the same configuration as that of the information processing device IPE illustrated in FIG. 1. The control program CNTL executed by the CPU0, however, programs, in an arbitrary FPGA, logic for executing tasks T of multiple types, causes the FPGA to execute the tasks T, and executes a process of measuring time periods tD for data transfer executed within the predetermined time period P before the process illustrated in FIG. 3. The control program CNTL calculates the data transfer time periods tD according to the aforementioned Equation (1). The control program CNTL may be executed by the CPU1. An example of a process to be executed by the control program CNTL is illustrated in FIG. 7.

A state (a0) of FIG. 6 illustrates an example in which the control program CNTL programs, in the FPGA0, the logic for executing the tasks T0 and T1, programs, in the FPGA1, the logic for executing the tasks T2 and T3, and measures the data transfer time periods tD as the data transfer costs for the tasks T. As a result of the measurement of the data transfer time periods tD, it becomes clear that the data transfer costs for the tasks T0 and T2 indicated by thick frames are relatively small and that the data transfer costs for the tasks T1 and T3 are relatively large. Specifically, the tasks T0 to T3 are classified into a group (of the tasks T0 and T2) for which the data transfer costs are relatively small and a group (of the tasks T1 and T3) for which the data transfer costs are relatively large.

Next, as illustrated in a state (a) of FIG. 6, the control program CNTL programs, in the FPGA0, the logic for executing the task T2 and programs, in the FPGA1, the logic for executing the task T1. Specifically, the logic for the group for which the data transfer costs are relatively small is programmed in the FPGA0, while the logic for the group for which the data transfer costs are relatively large is programmed in the FPGA1. Operations indicated in the state (a) to a state (f) of FIG. 6 are the same as the operations indicated in FIG. 2.

In the operations indicated in FIG. 6, it is difficult to estimate amounts D of data to be transferred for the tasks T within the predetermined time period P and the numbers K of times of the data transfer to be executed within the predetermined time period P. FIG. 6 illustrates the example in which, during the execution of data processing, the amounts D of the data transferred for the tasks T and the numbers K of times of the data transfer are measured and the data transfer costs are calculated. In the example illustrated in FIG. 6, even if the data transfer costs are not known upon the execution of the tasks T, the data transfer costs may be calculated during the execution of the data processing, and the logic for executing the tasks classified based on the data transfer costs may be programmed in the FPGA0 and the FPGA1.

FIG. 7 illustrates the example of the process of the control program CNTL executed by the CPU0 illustrated in the state (a0) of FIG. 6. The process illustrated in FIG. 7 is executed before the process illustrated in FIG. 3 in the case where the information processing device IPE starts data processing such as image processing, arithmetic processing, or statistical processing.

First, in step S2, the CPU0 programs, in arbitrary one or more FPGAs, logic for executing tasks of multiple types. The arbitrary one or more FPGAs may be either or both FPGA0 and FPGA1 or may be the FPGA2. In the state (a0) of FIG. 6, the logic for executing the tasks T0 and T1 is programmed in the FPGA0, and the logic for executing the tasks T2 and T3 is programmed in the FPGA1.

Next, in step S4, the CPU0 causes the FPGA0 to execute the tasks T0 and T1, causes the FPGA1 to execute the tasks T2 and T3, and executes the data processing. Then, in step S6, the CPU0 calculates amounts D of data transferred within the predetermined time period P and the numbers K of times of the data transfer executed within the predetermined time period P, and uses the data transfer rates S identified in advance and the overhead A to calculate the data transfer time periods tD as the data transfer costs according to the aforementioned Equation (1). In other words, the CPU0 calculates the data transfer costs by executing the tasks T0 to T3.

Next, in step S8, the CPU0 classifies, based on the results of calculating the data transfer costs, the tasks T into the group for which the data transfer costs are relatively small and the group for which the data transfer costs are relatively large. Then, the CPU0 programs the logic in the FPGA0 and the FPGA1 for each of the groups and terminates the process.

In the embodiment described with reference to FIGS. 6 to 7, an increase in the time periods for the data transfer between the FPGA0 and the FPGA2 may be minimized and the performance of the information processing device IPE may be improved, like the embodiment described with reference to FIGS. 1 to 5. In addition, in the embodiment described with reference to FIGS. 6 to 7, the following effect may be obtained. That is, even if the data transfer costs are not known upon the execution of the tasks T, the data transfer costs are calculated during the execution of the data processing, and the logic for the tasks classified based on the data transfer costs is programmed in the FPGA0 and the FPGA1.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A control device comprising:
a semiconductor device including a processor and a programmable circuit;
another programmable circuit coupled to the semiconductor device; and
another processor coupled to the semiconductor device and the other programmable circuit and configured to,
when it is detected that power consumed by the semiconductor device exceeds a threshold value, specify a first task from among tasks each of which logic is programmed in the programmable circuit, a data transfer cost for the first task between the processor and the programmable circuit being smaller than each of data transfer costs for other tasks included in the tasks,
program the logic of the first task into the other programmable circuit, and
control the first task to be executed by the logic of the first task in the other programmable circuit.

2. The control device according to claim 1,
the other processor further configured to calculate each data transfer cost of each of the tasks programmed in the programmable circuit,
wherein the first task is specified based on each the data transfer cost.

3. The control device according to claim 2, wherein each the data transfer cost is calculated based on time periods required for data transfer to be executed between the processor and the programmable circuit in response to the execution of each of the tasks within a predetermined time period.

4. The control device according to claim 3, wherein if amount of data to be transferred within the predetermined time period is “D”, data transfer rates between the processor and the programmable circuit is “S”, the number of times of the data transfer to be executed within the predetermined time period is “K”, and an overhead to be taken for data transfer executed one time is “A”, each the data transfer cost is calculated based on “(D/S)+(K×A)”.

5. The control device according to claim 1, the other processor further configured to:
after execution of programming the logic of the first task into the other programmable circuit, when it is detected that power consumed by the semiconductor device exceeds the threshold value, specify a second task from among the other tasks each, a data transfer cost for the second task between the processor and the programmable circuit being smaller than data transfer costs for the other tasks except the second task,
program the logic of the second task into the other programmable circuit, and
control the second task to be executed by the logic of the second task in the other programmable circuit.

6. The control device according to claim 1, the other processor further configured to:
after execution of programming the logic of the first task into the other programmable circuit, when it is detected that power consumed by the semiconductor device becomes equal to or lower than a second threshold value lower than the threshold value, reprograms the logic of the first task in the programmable circuit, and
control the first task to be executed by the logic of the first task in the programmable circuit.

7. The control device according to claim 1,
wherein every time power consumed by the second semiconductor device becomes equal to or lower than a second threshold value lower than the threshold value, the other processor reprograms, in the programmable circuit, any type of logic programmed in the other programmable circuit.

8. The control device according to claim 1, the other processor further configured to set the other programmable circuit to a power down state when no logic is programmed in the other programmable circuit.

9. The control device according to claim 1, the other processor further configured to set the programmable circuit to a power down state when no logic is programmed in the programmable circuit.

10. The control device according to claim 1, wherein the other processor is included in another semiconductor device including a second programmable circuit.

11. The control device according to claim 1, wherein the semiconductor device includes a semiconductor chip including the processor and includes a semiconductor chip including the programmable circuit.

12. The control device according to claim 1, wherein the semiconductor device includes a semiconductor chip including both the processor and the programmable circuit.

13. A control method executed by a computer, the method comprising:
when it is detected that power consumed by a semiconductor device exceeds a threshold value, specify a first task from among tasks each of which logic is programmed in a programmable circuit included in the semiconductor device, a data transfer cost for the first task between a processor included in the semiconductor device and the programmable circuit being smaller than each of data transfer costs for other tasks included in the tasks,
program the logic of the first task into another programmable circuit, the other programmable circuit being coupled to the semiconductor device and
control the first task to be executed by the logic of the first task in the other programmable circuit.

14. A non-transitory computer-readable medium storing a control program that causes a computer to execute a process comprising:
when it is detected that power consumed by a semiconductor device exceeds a threshold value, specify a first task from among tasks each of which logic is programmed in a programmable circuit included in the semiconductor device, a data transfer cost for the first task between a processor included in the semiconductor device and the programmable circuit being smaller than each of data transfer costs for other tasks included in the tasks;
program the logic of the first task into another programmable circuit, the other programmable circuit being coupled to the semiconductor device; and
control the first task to be executed by the logic of the first task in the other programmable circuit.
